(19) United States
(12) Patent Application Publication
(10) Pub. No.: US 2009/0162973 A1
(43) Pub. Date: Jun. 25, 2009

(54) GERMANIUM PRECURSORS FOR GST FILM DEPOSITION

(76) Inventors: Julien GATINEAU, Tsuchiura-shi (JP); Kazutaka YANAGITA, Tsukuba-shi (JP); Shingo OKUBO, Tsukuba-shi (JP)

Correspondence Address: AIR LIQUIDE;Intellectual Property, 2700 POST OAK BOULEVARD, SUITE 1800, HOUSTON, TX, 77056, US

(21) Appl. No.: 12/341,685

(22) Filed: Dec. 22, 2008

Related U.S. Application Data
(60) Provisional application No. 61/015,896, filed on Dec. 21, 2007.

(51) Int. Cl. H01L 21/06; H01L 21/31; C07F 7/30

(52) U.S. Cl. 438/102; 438/482; 556/87; 257/E21.24; 257/E21.068

(57) ABSTRACT

A method for depositing a germanium containing film on a substrate is disclosed. A reactor, and at least one substrate disposed in the reactor, are provided. A germanium containing precursor is provided and introduced into the reactor, which is maintained at a temperature of at least 100° C. Germanium is deposited onto the substrate through a deposition process to form a thin film on the substrate.

### CROSS REFERENCE TO RELATED APPLICATIONS

The present application claims the benefit of U.S. Provisional Application Ser. No. 61/015,896, filed Dec. 21, 2007, herein incorporated by reference in its entirety for all purposes.

### BACKGROUND

1. Field of the Invention

This invention relates generally to the field of semiconductor, photovoltaic, flat panel or LCD-TFT device fabrication.

2. Background of the Invention

Phase change materials are used in standard bulk silicon technologies to form the memory elements of nonvolatile memory devices. Phase change materials exhibit at least two different states, one being amorphous and the other(s) crystalline. The amorphous state is characterized by the absence of crystallinity or the lack of long range order, as opposed to crystallized states, which are characterized by a long range order. Accordingly, the order in a unit cell, which is repeated a large number of times, is representative of the whole material.

Each memory cell in a nonvolatile memory device may be considered as a variable resistor that reversibly changes between higher and lower resistivity states corresponding to the amorphous state and the crystalline state of the phase change material. The states can be identified because each state can be characterized by a conductivity difference of several orders of magnitude. In these devices, the phase changes of the memory element are performed by direct heating of the phase change material with high programming currents. Conventionally, bipolar transistors are used to deliver high programming currents by directly heating the phase change material. The high current produces direct heating of the phase change material, which can cause the phase change material to degrade over repeated programming operations, thereby reducing memory device performance.

Among the materials of practical use today, most contain germanium. Of those materials, the most extensively studied material is Ge₂Sb₂Te₅. While the deposition can be conventionally performed by plasma vapor deposition (PVD) techniques such as sputtering, chemical vapor deposition (CVD) and atomic layer deposition (ALD) and related techniques including pulse-CVD, remote plasma CVD, plasma assisted CVD, plasma enhanced ALD, a variety of materials are now being studied in order to overcome the challenges of deposition in complex structures, including those consisting of trenches. The use of Ge(tBu)₄, Sb(iPr)₃ and Te(iPr)₂ has been reported, for instance. The use of such molecules for the deposition of germanium-antimony-tellurium (GST) material raises some difficulties, however. For example, many germanium containing precursors are insufficiently thermally stable for a reproducible process. Although there have been significant advancements in the art, there is continuing interest in the design and use of precursor compounds with improved stability.

Consequently, there exists a need for germanium containing precursors which are stable enough to allow deposition at low temperatures.

### BRIEF SUMMARY

The invention provides novel methods and compositions for the deposition of germanium containing films, or germanium antimony telluride (“GST”) films on a substrate. In an embodiment, a method for depositing a germanium or GST type film on a substrate comprises providing a reactor, and at least one substrate disposed in the reactor. A germanium containing precursor is provided, where the precursor is of the general formula:

GeRₓ¹(NR²R³)₍₄₋ₓ₎

where R¹ is independently selected from among: hydrogen; a halogen (e.g. chlorine, fluorine, bromine, iodine); a C1-C6, linear or branched, alkyl; an alkoxide; an alkylsilyl; a fluoroalkyl; an alkyltelluryl; an alkylantomnyl; and an alkyl germyl. R² and R³ are also independently selected from hydrogen; a C1-C6, linear or branched, alkyl; an alkylamino; an alkylimino; an alkoxy; an alkylsilyl; or a fluoroalkyl; and x is an integer between 1 and 3, inclusive. The germanium containing precursor is introduced into the reactor. The reactor is maintained at a temperature of at least 100° C., and at least part of the precursor is deposited onto the substrate to form a germanium containing film.

In an embodiment, a germanium precursor comprises a precursor of the general formula:

GeRₓ¹(NR²R³)₍₄₋ₓ₎

where R¹ is independently selected from among: hydrogen; a halogen (e.g. chlorine, fluorine, bromine, iodine); a C1-C6, linear or branched, alkyl; an alkoxide; an alkylsilyl; a fluoroalkyl; an alkyltelluryl; an alkylantomnyl; and an alkyl germyl. R² and R³ are also independently selected from hydrogen; a C1-C6, linear or branched, alkyl; an alkylamino; an alkylimino; an alkoxy; an alkylsilyl; or a fluoroalkyl; and x is an integer between 1 and 3, inclusive.

Other embodiments of the current invention may include, without limitation, one or more of the following features:
maintaining the reactor at a temperature between about 100° C. and about 500° C., and preferably between about 150° C. and about 350° C.;
maintaining the reactor at a pressure between about 1 Pa and about 10⁵ Pa, and preferably between about 25 Pa and about 10³ Pa;
introducing at least one reducing gas into the reactor, wherein the reducing gas is at least one of: hydrogen; ammonia; silane; disilane; trisilane; hydrogen radicals; and mixtures thereof:
the germanium precursor and the reducing gas are introduced into the chamber either substantially simultaneously or sequentially;
the germanium precursor and the reducing gas are introduced into the chamber substantially simultaneously and the chamber is configured for chemical vapor deposition;
the germanium precursor and the reducing gas are introduced into the chamber sequentially and the chamber is configured for atomic layer deposition;
introducing at least one oxidizing gas into the reactor, wherein the oxidizing gas is at least one of: oxygen, ozone; water vapor;

hydrogen peroxide; oxygen containing radicals (e.g. O° or OH°); and mixtures thereof;
the germanium precursor and the oxidizing gas are introduced into the chamber either substantially simultaneously or sequentially;
the germanium precursor and the oxidizing gas are introduced into the chamber substantially simultaneously and the chamber is configured for chemical vapor deposition;
the germanium precursor and the oxidizing gas are introduced into the chamber sequentially and the chamber is configured for atomic layer deposition;
a germanium containing thin film coated substrate;
introducing at least one tellurium containing precursor and at least one antimony containing precursor; and depositing at least part of the tellurium and antimony containing precursors onto the substrate to form a germanium, tellurium and antimony (GST) containing film; and
the germanium precursor is at least one of: GeH(NMe₂)₃; GeH(NMeEt)₃; GeH(NEt₂)₃; Ge(SiMe₃)(NEt₂)₃; GeH₂(NEt₂)₂; GeH₂(NHEt)₂; GeH₂(NMe₂)₂; GeH₂(NMeEt)₂; GeH₂(NHt-Bu)₂; GeH₃(NEt₂); GeH₃(NMe₂); GeH₃(NMeEt); and GeH₃(NHt-Bu).

The foregoing has outlined rather broadly the features and technical advantages of the present invention in order that the detailed description of the invention that follows may be better understood. Additional features and advantages of the invention will be described hereinafter that form the subject of the claims of the invention. It should be appreciated by those skilled in the art that the conception and the specific embodiments disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### Notation and Nomenclature

Certain terms are used throughout the following description and claims to refer to various components and constituents. This document does not intend to distinguish between components that differ in name but not function.

As used herein, the term “alkyl group” refers to saturated functional groups containing exclusively carbon and hydrogen atoms. Further, the term “alkyl group” may refer to linear, branched, or cyclic alkyl groups. Examples of linear alkyl groups include without limitation, methyl groups, ethyl groups, propyl groups, butyl groups, etc. Examples of branched alkyls groups include without limitation, t-butyl. Examples of cyclic alkyl groups include without limitation, cyclopropyl groups, cyclopentyl groups, cyclohexyl groups, etc.

As used herein, the abbreviation, “Me,” refers to a methyl group; the abbreviation, “Et,” refers to an ethyl group; the abbreviation, “t-Bu,” refers to a tertiary butyl group.

As used herein, the term “independently” when used in the context of describing R groups should be understood to denote that the subject R group is not only independently selected relative to other R groups bearing different superscripts, but is also independently selected relative to any additional species of that same R group. For example in the formula GeRₓ¹(NR²R³)₍₄₋ₓ₎, where x is 2 or 3, the two or three R¹ groups need not be identical to each other or to R² or to R³.

### DESCRIPTION OF PREFERRED EMBODIMENTS

Generally, embodiments of the current invention relate to methods and compositions for the deposition of germanium and GST type films on a substrate. A reactor and at least one substrate disposed within the reactor are provided. A germanium containing precursor is provided, where the germanium containing precursor is of the general formula:

GeRₓ¹(NR²R³)₍₄₋ₓ₎

where R¹ is independently selected from among: hydrogen; a halogen (e.g. chlorine, fluorine, bromine, iodine); a C1-C6, linear or branched, alkyl; an alkoxide; an alkylsilyl; a fluoroalkyl; an alkyltelluryl; an alkylantomnyl; and an alkyl germyl. R² and R³ are also independently selected from hydrogen; a C1-C6, linear or branched, alkyl; an alkylamino; an alkylimino; an alkoxy; an alkylsilyl; or a fluoroalkyl; and x is an integer between 1 and 3, inclusive.

In some embodiments, at least one of the ligands may be, but are not limited to, one of: methyl (—CH₃), ethyl (—C₂H₅), isopropyl (—CH(CH₃)₂), methoxy (—OCH₃), ethoxy (—OC₂H₅), isopropoxy (—OCH(CH₃)₂), dimethylamino (—N(CH₃)₂), diethylamino (—N(C₂H₅)₂), methylethylamino (—N(CH₃)(C₂H₅), ethylamino (—NC₂H₅), silyl (—SiH₃), trimethylsilyl (—Si(CH₃)₃), triethylsilyl (—Si(C₂H₅)₃), or t-butylimido (═N(CH₂)CH(CH₃)₂.

In some embodiments, the germanium precursor having the abovementioned formula may be one of: GeH(NMe₂)₃; GeH(NMeEt)₃; GeH(NEt₂)₃; Ge(SiMe₃)(NEt₂)₃; GeH₂(NEt₂)₂; GeH₂(NHEt)₂; GeH₂(NMe₂)₂; GeH₂(NMeEt)₂; GeH₂(NHt-Bu)₂; GeH₃(NEt₂); GeH₃(NMe₂); GeH₃(NMeEt); or GeH₃(NHt-Bu).

In some embodiments, further precursors containing tellurium and antimony may also be provided and deposited on the substrate. By providing germanium, tellurium and antimony containing precursors, a chalcogenide glass type film may be formed on the substrate, for instance, GeTe—Sb₂Te₃ or Ge₂Sb₂Te₅.

Precursors may generally be delivered to the reactor chamber by passing a carrier gas through the precursor storage container. Suitable carrier gases may include inert gases such as nitrogen, helium, and argon, hydrogen, and mixtures thereof. The carrier gas may be introduced below the surface of the precursor source, and it may pass up through the precursor to the headspace of the container, thereby entraining precursor or mixing with precursor vapor. The entrained or mixed vapor may then be sent to the reactor.

The deposition reactor or deposition chamber may be a heated vessel which has at least one or more substrates disposed within. The deposition reactor has an outlet, which may be connected to a vacuum pump to allow by products to be removed from the chamber, or to allow the pressure within the reactor to be modified or regulated. The temperature in the chamber is normally maintained at a suitable temperature for the type of deposition process which is to be performed. In some cases, the chamber may be maintained at a lower temperature, for instance when the substrates themselves are heated directly, or where another energy source (e.g. plasma or radio frequency source) is provided to aid in the deposition.

Conventional substrates for deposition in semiconductor manufacturing include substrates such as silicon, gallium arsenide, indium phosphide, etc. Substrates may contain one or more additional layers of materials, which may be present from a previous manufacturing step. Dielectric and conductive layers are examples of these.

Depending on the particular process parameters, deposition may take place for a varying length of time. Generally, deposition may be allowed to continue as long as desired to produce a film with the necessary properties. Typical film thicknesses may vary from several hundred angstroms to several hundreds of microns, depending on the specific deposition process.

In some embodiments, the deposition chamber is maintained at a temperature greater than about 100° C. In some embodiments, the tempearature is maintained between about 100° C. and about 500° C., preferably, between about 150° C. Likewise, the pressure in the deposition chamber is maintained at a pressure between about 1 Pa and about 10⁵ Pa, and preferably between about 25 Pa, and about 10³ Pa.

In some embodiments, a reducing gas is also introduced into the reaction chamber. The reducing gas may be one of hydrogen; ammonia; silane; disilane; trisilane; hydrogen radicals; and mixtures thereof. When the mode of deposition is chemical vapor deposition, the germanium precursor and the reducing gas may be introduced to the reaction chamber substantially simultaneously. When the mode of deposition is atomic layer deposition, the germanium precusor and the reducing gas may be introduced sequentially, and in some cases, there may be an inert gas purge introduced between the precursor and reducing gas.

In some embodiments, an oxidizing gas is also introduced into the reaction chamber. The oxidizing gas may be one of oxygen, ozone; water vapor; hydrogen peroxide; oxygen containing radicals (e.g. O° or OH°); and mixtures thereof. When the mode of deposition is chemical vapor deposition, the germanium precursor and the oxidizing gas may be introduced to the reaction chamber substantially simultaneously. When the mode of deposition is atomic layer deposition, the germanium precursor and the oxidizing gas may be introduced sequentially, and in some cases, there may be an inert gas purge introduced between the precursor and oxidizing gas.

By performing deposition according to the various embodiments of the current invention, a substrate with a thin film coat containing germanium or GST will be achieved.

While embodiments of this invention have been shown and described, modifications thereof can be made by one skilled in the art without departing from the spirit or teaching of this invention. The embodiments described herein are exemplary only and not limiting. Many variations and modifications of the composition and method are possible and within the scope of the invention. Accordingly the scope of protection is not limited to the embodiments described herein, but is only limited by the claims which follow, the scope of which shall include all equivalents of the subject matter of the claims.

What is claimed is:

1. A method for depositing a GST type thin film on to one or more substrates, comprising:
a) providing a reactor, and at least one substrate disposed in the reactor;
b) providing at least one germanium containing precursor of the general formula:
GeRₓ¹(NR²R³)₍₄₋ₓ₎
wherein:
R¹ is independently selected from among: hydrogen; a halogen; a C1-C6, linear or branched, alkyl; an alkoxide; an alkylsilyl; a fluoroalkyl; an alkyltelluryl; an alkylantomnyl; and an alkyl germyl;
each R² and R³ are independently selected from among H; a C1-C6, linear or branched, alkyl; an alkylamino; an alkylimino; an alkoxy; an alkylsilyl; or a fluoroalkyl; and
x is an integer between 1 and 3 inclusive (i.e. 1≦x≦3);
c) introducing the germanium containing precursor into the reactor;
d) maintaining the reactor at a temperature of at least 100° C.; and
e) depositing at least part of the germanium precursor onto the substrate to form a germanium containing thin film.

2. The method of claim 1, further comprising maintaining the reactor at a temperature between about 100° C. to about 500° C.

3. The method of claim 2, further comprising maintaining the reactor at a temperature between about 150° C. and about 350° C.

4. The method of claim 1, further comprising maintaining the reactor at a pressure between about 1 Pa and about 10⁵ Pa.

5. The method of claim 4, further comprising maintaining the reactor at a pressure between about 25 Pa and about 10³ Pa.

6. The method of claim 1, further comprising introducing at least one reducing gas into the reactor, wherein the reducing gas comprises at least one member selected from the group consisting of: H₂; NH₃; SiH₄; Si₂H₆; Si₃H₈; hydrogen radicals; and mixtures thereof.

7. The method of claim 6, wherein the germanium precursor and the reducing gas are introduced into the chamber either substantially simultaneously, or sequentially.

8. The method of claim 7, wherein the reducing gas and the germanium precursor are introduced into the chamber substantially simultaneously, and the chamber is configured for chemical vapor deposition.

9. The method of claim 7, the reducing gas and the germanium precursor are introduced into the chamber sequentially, and the chamber is configured for atomic layer deposition.

10. The method of claim 1, further comprising introducing at least one oxidizing gas into the reactor, wherein the oxidizing gas comprises at least one member selected from the group consisting of: O₂; O₃; H₂O; H₂O₂; oxygen containing radicals (e.g. O° or OH°); and mixtures thereof.

11. The method of claim 10, wherein the germanium precursor and the oxidizing gas are introduced into the chamber either substantially simultaneously, or sequentially.

12. The method of claim 11, wherein the oxidizing gas and the germanium precursor are introduced into the chamber substantially simultaneously, and the chamber is configured for chemical vapor deposition.

13. The method of claim 11, the oxidizing gas and the germanium precursor are introduced into the chamber sequentially, and the chamber is configured for atomic layer deposition.

14. The method of claim 1, wherein the germanium precursor comprises GeH(NMe₂)₃.

15. The method of claim 1, wherein the germanium precursor comprises GeH(NMeEt)₃.

16. The method of claim 1, wherein the germanium precursor comprises GeH(NEt₂)₃.

17. The method of claim 1, wherein the germanium precursor comprises Ge(SiMe₃)(NEt₂)₃.

18. The method of claim 1, wherein the germanium precursor comprises GeH₂(NEt₂)₂.

19 The method of claim 1, wherein the germanium precursor comprises GeH₂(NHEt)₂.

20. The method of claim 1, wherein the germanium precursor comprises GeH₂(NMe₂)₂.

21. The method of claim 1, wherein the germanium precursor comprises GeH₂(NMeEt)₂.

22. The method of claim 1, wherein the germanium precursor comprises GeH₂(NHt-Bu)₂.

23. The method of claim 1, wherein the germanium precursor comprises GeH₃(NEt₂).

24. The method of claim 1, wherein the germanium precursor comprises GeH₃(NMe₂).

25. The method of claim 1, wherein the germanium precursor comprises GeH₃(NMeEt).

26. The method of claim 1, wherein the germanium precursor comprises GeH₃(NHt-Bu).

27. The method of claim 1, further comprising introducing at least one tellurium containing precursor and at least one antimony containing precursor; and depositing at least part of the tellurium and antimony containing precursors onto the substrate to form a germanium, tellurium and antimony containing film.

28. A germanium containing thin film coated substrate comprising the product of the method of claim 1.

29. A germanium precursor comprising a precursor of the general formula:
GeRₓ¹(NR²R³)₍₄₋ₓ₎
wherein:
R¹ is independently selected from among: hydrogen; a halogen; a C1-C6, linear or branched, alkyl; an alkoxide; an alkylsilyl; a fluoroalkyl; an alkyltelluryl; an alkylantomnyl; and an alkyl germyl;
each R² and R³ are independently selected from among H; a C1-C6, linear or branched, alkyl; an alkylamino; an alkylimino; an alkoxy; an alkylsilyl; or a fluoroalkyl; and
x is an integer between 1 and 3 inclusive (i.e. 1≦x≦3);
